(19) United States
(12) Patent Application Publication
(10) Pub. No.: US 2016/0049937 A1
(43) Pub. Date: Feb. 18, 2016

(54) ACTIVITY CORRELATION BASED OPTIMAL CLUSTERING FOR CLOCK GATING FOR ULTRA-LOW POWER VLSI

(71) Applicants: Qiang Tong, Chicago, IL (US); Kyuwon Choi, Oak Brook, IL (US)

(72) Inventors: Qiang Tong, Chicago, IL (US); Kyuwon Choi, Oak Brook, IL (US)

(21) Appl. No.: 14/827,843

(22) Filed: Aug. 17, 2015

Related U.S. Application Data
(60) Provisional application No. 62/038,022, filed on Aug. 15, 2014.

(51) Int. Cl. H03K 19/00; H03K 3/037; G06F 1/04

(52) U.S. Cl. CPC H03K 19/0016; G06F 1/04; H03K 3/037

(57) ABSTRACT

A clustering bus-specific clock gating method is described to reduce the dynamic power consumed by redundant clock ticks in gate-level. The method exploits correlations between flip-flops for clock gating. An activity correlation matrix is introduced to describe the correlations between the flip-flops. Based on activity correlation information, the flip-flops are classified into several clusters. A payoff function is also described to find an optimal classification scheme. Based on the classification strategy, flip-flop clusters that are less active and more correlated will be gated.

### CROSS REFERENCE TO RELATED APPLICATION

This application claims the benefit of U.S. Provisional Patent Application, Ser. No. 62/038,022, filed on 15 Aug. 2014. The co-pending Provisional Patent Application is hereby incorporated by reference herein in its entirety and is made a part hereof, including but not limited to those portions which specifically appear hereinafter.

### BACKGROUND OF THE INVENTION

This invention relates generally to reducing power consumption of integrated circuits, and, more particularly, to clock gating for reducing the dynamic power consumption of very large scale integrated (VLSI) circuits.

Advances in CMOS technology have enabled higher integration and higher operational frequencies in present VLSI design. This is because the early VLSI designers were concerned with area and speed more than the power consumption. In recent years, however, the popularity of portable devices, mostly powered by batteries, has made the power dissipation a comparable factor to area and speed.

One of the largest dynamic power consuming components of a synchronous circuit is the clock distribution network, which is typically responsible for 30%-40% for the dynamic power dissipation. Two factors generally account for this phenomenon: 1) that the clock signal has a toggle rate of 1, which is the maximal value; 2) that the clock network drives large amounts of cells, including buffers, flip-flops, etc. These large amounts of fan-out cells make the load capacitance of the clock distribution network very large. The above two factors make the clock distribution network consume a large portion of power consumption. Power can be saved by optimizing the clock distribution networks. In real sequential circuits, the inputs of sequential logics do not toggle in every cycle. Sequential logic wastes energy when the input does not toggle and the clock signal still charges and discharges the load of the clock distribution network. Only sequential components need clock signals, and in sequential circuits, the most used devices are flip-flop circuits. Flip-flops are thought to be one of the most energy-consuming components of digital circuits. Several power management techniques have been proposed to reduce power dissipation by eliminating the unnecessary transitions of various signals in the circuits. These techniques generally manage the idleness and the shutdown of parts of the circuits to reduce power dissipation. Among those methods, the clock gating (CG) technique is the most well-known and common technique used for dynamic power reduction. CG has been studied for a long time, and a number of methods have been proposed to improve the efficiency of CG. Few conventional CG techniques take activity correlation into account, while the activity correlation plays a very important role in determining the efficiency of CG.

CG is not simply gating as many sequential devices as possible. There is a tradeoff between the power reduction by CG and extra power consumed by the additional gates and latches for CG. There is a continuing need for improved power saving and/or clock gating techniques for integrated circuits.

### SUMMARY OF THE INVENTION

A general object of the invention is to provide a method, and software for automatically implementing the method, for correlating activity between flip-flops for clock gating, to reduce the dynamic power consumption of very large scale integrated (VLSI) circuits. A heuristic method and algorithm is proposed to find a sub-optimal clock gating scheme, which obtains more power reduction compared to existing techniques.

The general object of the invention can be attained, at least in part, through a method for improving power consumption in integrated circuits by grouping circuits, such as flip-flop circuits, by activity correlation, such as clock toggles, and clock gating as a function of the grouped circuits. Embodiments of the method incorporate grouping the circuits in an activity correlation matrix, with such correlation desirably being performed during a predetermined number of clock cycles.

By using the activity correlation matrix of this invention, the method and corresponding software can find groups of circuits that are correlated closely and gate them together. By considering activity correlation in the clock gating technique, power consumption can be reduced. In some embodiments of this invention, the method includes: grouping the circuits in an activity correlation matrix; sorting the circuits from the activity correlation matrix in ascending order as a function of a toggle rate; clustering the circuits having a highest correlation in a group; continuing the addition of circuits having the next highest correlation to the group until a power gain is no longer increasing and/or is above a predetermined threshold; and gating the circuits not within the group.

The invention further includes a method for improving power consumption in integrated circuits by: correlating flip-flop circuits as a function of circuit activity; classifying the correlated circuits into a plurality of clusters; and gating at least one of the clusters including lower activity flip-flop circuits. Embodiments of the invention further include determining a number of clusters to gate as a function of power savings, wherein the power savings is determined as a function of power reduction by the gating and power used for the correlating and classifying steps. In some embodiments, the correlation is based upon a predetermined input vector timeframe.

Some embodiments according to this invention can be used in power optimization in gate-level of VLSI/ASIC design flow, for example, for the purpose of reducing dynamic power. More broadly, the clustering technique can be also used for power gating, which can also be applied to groups of logic gates which are more correlated, to reduce leakage power consumption.

In some embodiments according to this invention, the algorithm used for clustering is based on heuristics, which can only obtain a sub-optimal solution for clustering. Also, the algorithm may suffer from local optimization problems. Heuristics is widely used to solve NP-hard problems in computer science. The sub-optimal and local optimization problems can be traded off by time and accuracy.

The method and software/system of this invention are desirably automatically executed or implemented on and/or through a computing platform. Such computing platforms generally include one or more processors for executing the method steps stored as coded software instructions, at least one recordable medium for storing the software and/or matrix or other data produced by the method, an input/output (I/O) device, and a network interface capable of connecting either directly or indirectly to the Internet or other network.

Other objects and advantages will be apparent to those skilled in the art from the following detailed description taken in conjunction with the appended claims and drawings.

### BRIEF DESCRIPTION OF THE DRAWINGS

FIGS. 1 and 2 illustrate correlation based clock gating, according to one embodiment of this invention.

FIG. 3 shows a gated flip-flop of a bus-specific clock gating structure, according to one embodiment of this invention.

FIG. 4 illustrates pseudo code for a clustering algorithm according to one embodiment of this invention.

FIG. 5 includes plots summarizing payoff function result versus power measurement.

FIG. 6 is a plot comparing the performances of the three clock gating techniques.

FIG. 7 summarizes a comparison between OBSC and CBSC, from the examples below, using a Synopsys Power Compiler.

### DESCRIPTION OF THE INVENTION

The present invention provides a clustering bus-specific clock (CBSC) gating technique, which produces a better performance on power reduction. In the perspective of mathematics, the CBSC gating removes the constraint on group numbers, and obtains a better solution for the clock gating optimization problem. The method exploits the activity correlations between flip-flops, and classifies them into several clusters. In addition, the method uses a different training input vector and test input vector. To exploit the correlations between flip-flops, embodiments of this invention incorporate an activity correlation matrix. In some embodiments of this invention determine a payoff function, which is more efficient, to find an optimal classification scheme.

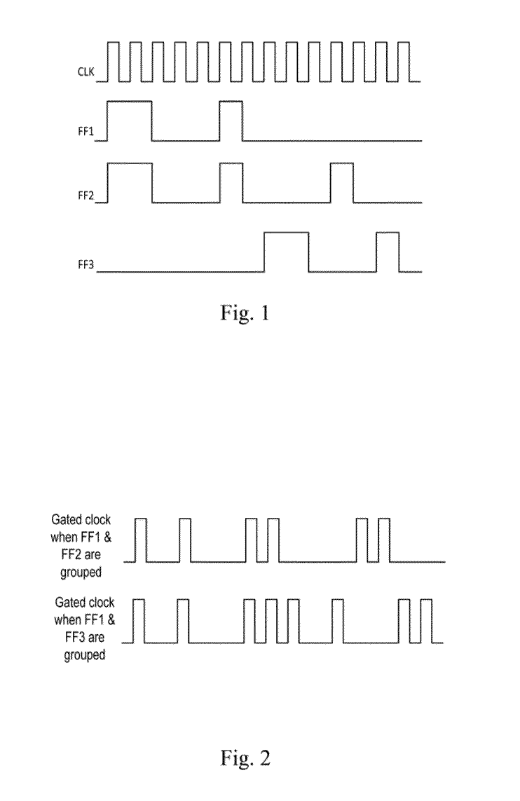

FIGS. 1 and 2 illustrate correlation based clock gating. In FIG. 1, there are three flip-flops (FFs): FF1, FF2 and FF3. FF1 and FF3 have the same toggle numbers, FF2 has two more toggles. Within a same number of clock cycles (as in FIG. 1, the number of cycles is 14), toggle rates (TR) of FF1, FF2 and FF3, which are denoted as TR(1), TR(2) and TR(3), are 4/14, 6/14 and 4/14 respectively. If two FFs have to be gated, the known techniques, which just take the TR into consideration, will choose FF1 and FF3 as the gated group. While actually, it is see from FIG. 2 that it saves more wasting clock toggles when FF1 and FF2 are gated together.

From FIG. 1, FF1 and FF2 are more correlated according to embodiments of this invention, since they are more likely to toggle together. FIG. 2 shows the clock signal of gating different groups, and it can be seen that when FF1 and FF2 are gated together, there will be less clock toggles, which means less power consumption.

The method of this invention exploits activity correlations between the flip-flops. In some embodiments of this invention the activity correlation is based on the assumption that some flip-flops in a specific design might have certain relations which make them tend to toggle together. In some embodiments, the basic concept of activity correlation is defined as: given a certain input vector, during a period in which the input vector is effective, the toggle number relations between devices (e.g., flip-flop, used herein for description). The toggle numbers of each flip-flop are counted during the period when a certain input vector is in effect, and these toggle numbers to some extent reflect the action of the flip-flop to the certain input vector. If two flip-flops have the same or similar toggle patterns, then they are considered related by activity; to the contrary, if the two flip-flops have very large toggle number difference, then they are considered activity irrelative. In the activity correlation matrix building process, the correlation of each flip-flop is statistically counted for a certain time period, for example 2 clock cycles illustrated below in Table 1.

TABLE 1

| | | FF1 toggle | FF2 toggle | FF3 toggle |
|---|---|---|---|---|
| period | Clock ticks | counts | counts | counts |
| 1 | 1-2 | 1 | 1 | 0 |
| 2 | 3-4 | 1 | 1 | 0 |
| 3 | 5-6 | 1 | 1 | 0 |
| 4 | 7-8 | 1 | 1 | 1 |
| 5 | 9-10 | 0 | 0 | 1 |
| 6 | 11-12 | 0 | 2 | 0 |
| 7 | 13-14 | 0 | 0 | 2 |

The next step of building the activity correlation matrix calculates the correlation. Using FF1 as an example, the correlation between FF1 and FF2, FF3 is calculated. First, calculate the correlation between FF1 and FF2 by subtracting the toggle count of FF2 from that of FF1 in each period, and summing the absolute values of differences: Sum dif(FF1,FF2)=|1-1|+|1-1|+|1-1|+|1-1|+|0-0|+|0-2|+|0-0|=2, Sum_dif(FF1,FF3)=|1-0|+|1-0|+|1-0|+|1-1|+|0-1|+|0-0|+|0-2|=6. Table 2 summarizes the results for the correlation of FF1, FF2, and FF3.

TABLE 2

| | FF1 | FF2 | FF3 |
|---|---|---|---|
| FF1 | 0 | 2 | 6 |
| FF2 | 2 | 0 | 8 |
| FF3 | 6 | 8 | 0 |

Next, the results are normalized by:

cor(FF1,FF2)=(max_sum_dif−Sum_dif(FF1,FF2)/max_sum_dif)=(8−2)/8

The resulting activity correlation matrix is shown below. From the activity correlation matrix it is clear that FF1 and FF2 are more correlated than FF1 and FF3.

| | FF1 | FF2 | FF3 |
|---|---|---|---|
| FF1 | 1 | ¾ | ¼ |
| FF2 | ¾ | 1 | 0 |
| FF3 | ¼ | 0 | 1 |

In embodiments of this invention, the groups of the circuits in an activity correlation matrix are then sorted in ascending order as a function of a toggle rate. The method then clusters the circuits based upon correlation rate, with the highest correlation in one group. Circuits can be continually adding to the cluster, on the basis of having the next highest correlation to the group, until a power gain is no longer increasing and/or is above a predetermined threshold. Any flip-flops not within the clustered group can be gated to save power. In some embodiments according to this invention, a procedure of the clustering algorithm is summarized as:
(1) Obtain the activity correlation matrix;
(2) Sort the flip-flops in ascending order based on their toggle rate, and put all of them in set A;
(3) Get a flip-flop FFx from set A, which has the least toggle rate. If A is empty, go to (8);
(4) Get the most correlated flip-flops of FFx from A based on the activity correlation matrix, and group them together, if A is empty, go to (8);
(5) Then calculate the payoff with a specific payoff function;
(6) If the payoff is greater than 0, make the flip-flops into the same group, and remove them from set A; then go to (4);
(7) If the payoff is greater than 0 and A is not empty, go to (3); and
(8) Return.

The present invention is described in further detail in connection with the following examples which illustrate or simulate various aspects involved in the practice of the invention. It is to be understood that all changes that come within the spirit of the invention are desired to be protected and thus the invention is not to be construed as limited by these examples.

As described above, circuit activity information is used to build an activity correlation matrix. In this example, a value change dump (VCD) file was used, which supplied sufficient information of the activities of each cell in a design. To make the correlation information good enough to resemble the physical circuit, a certain amount of random input vectors were used. Actually, the greater number of input vectors used, the more accurate the correlation model is. One consideration for sequential circuits, is that there are usually memories elements (latch or flip-flop). To record the memory elements information, each input vector was held for several cycles in the training test bench. Note that the input was only held for several cycles in the training input vector (for generating the Activity correlation matrix). When it comes to a real application, this constraint is not a concern, and the input vector can change every cycle if necessary.

In the training test bench, every randomly generated input vector was held for 10 cycles. Each period was named as a duration, during which one certain input vector was held. Supposing a total of M input vectors, there were a total of M durations to count. In every duration, the toggle numbers of each flip-flop output were counted, and Θₖ=[α₁, α₂, . . . , α_{N}] was used to denote the counting record for one duration, where Θₖ is defined as toggle number vector, k denotes the kₜₕ duration, αᵢ denotes the toggle numbers of the iₜₕ flip-flop, N denotes the number of flip-flops. An activity N×N correlation matrix Ψ is then defined. Each row of the activity correlation matrix is defined as

$$Ψ ( i , \text{:} ) = {\sum }_{k = 0}^{M} \vert {α}_{i}^{k} - {Θ}_{k} \vert ;$$

where αᵢ^{k} denotes the toggle numbers of the iₜₕ flip-flop in the kₜₕ duration, M denotes the duration numbers. After normalization, the activity correlation matrix can be obtained, which has the same properties as the correlation matrix in statistics: 1) it is a symmetric matrix; 2) the diagonal entries are all 1.

As the activity correlation matrix supplies the activity correlations information, the flip-flops can easily be classified. However, a payoff function should be defined to measure the performance of different classification schemes, and hence, to find an optimal classification. In embodiments of this invention, the payoff function is defined to consider the tradeoff of the power reduction by clock gating and extra power dissipated by the additional gates and latches for clock gating as discussed above.

L. Li et al., “Activity-driven optimized bus-specific-clock-gating for ultra-low-power smart space applications,” Journal of IET Communications, vol. 5, iss. 17, pp. 2501-2508 (2011), provides a power estimation model (referred to as “OBSC”), which was used to find an optimal classification scheme. Because the OBSC technique needs to iterate many times to find an optimal scheme, the efficiency of the power estimation model is very critical. Unfortunately, the power estimation model is not so efficient. With the increasing scale of the circuit, the computation complexity of the OBSC increases exponentially. One reason for this is because the power estimation model is so inefficient that it is impossible to get a result within an acceptable time. In some embodiments of this invention, the power consumption is not estimated, but instead a payoff function is built or determined, which can indicate the tradeoff between the power saved by clock gating and the additional power caused by the clock gating logics. This payoff function is relatively easier, more efficient, and, most importantly, it is sufficient to measure the power reduction of the different clustering scheme.

Clock gating techniques are mainly used to reduce the dynamic power of digital circuits. Generally, dynamic power can be categorized into two parts: 1) power dissipated by charging and discharging the load capacitance, hereby named switching power; 2) power caused by short circuit current, hereby named short circuit power. Switching power is given by:

P_{SW}=α·C_{L}·V_{DD}²·f (1)

where P_{SW} is the switching power, α is the activity factor (e.g., a toggle rate), C_{L} is the load capacitance, V_{DD} is the supply voltage, and f is the working frequency.

Unlike the switching power, the short circuit power varies with many factors. It is strongly sensitive to the ratio of the threshold voltage to supply voltage: Vₜₕ/V_{DD}. It has also been observed dependent on the input ramp, the load capacitance and the transistor size. Because of these multiple dependencies, the short circuit power estimation models are usually complex. S. Turgis et al., “Explicit evaluation of short-circuit power dissipation for CMOS logic structures,” Proceedings of ISLPD, Dana Point Resort, April 1995, pp-129-134, proposed a first order formulation for short circuit power dissipation. The main idea of this formulation is using the parameter C_{SC}, short circuit capacitance, which has no physical meaning and is just an equivalent way to represent the charge transfer. With this ‘short circuit capacitance’, the short circuit power can be expressed in the same way as switching power:

P_{SC}=α·C_{SC}·V_{DD}²·f (2)

where P_{SC} is the short circuit power, and C_{SC} is the short circuit capacitance. With equation (1) and (2), the total dynamic power can be given as:

P_{dynamic}=α·(C_{L}+C_{SC})·V_{DD}²·f (3)

The clock gating technique can save dynamic power by eliminating wasted clock toggles. However, the additional logics introduced by the clock gating consume extra power. So in embodiments of this invention, a payoff function consists of two parts: 1) saved power by clock gating: P_{saved}; and 2) extra power introduced by clock gating logics: Pₑₓₜᵣₐ. The payoff function can be provided by equation (4):

F_{payoff}=P_{saved}−Pₑₓₜᵣₐ (4)

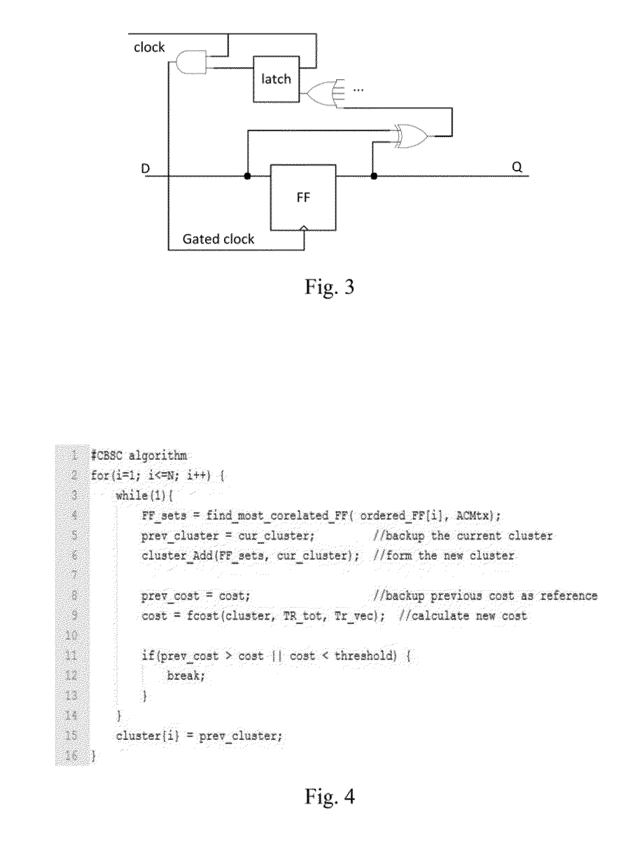

FIG. 3 shows a gated flip-flop of bus-specific clock gating structure. From the viewpoint of the flip-flop, there is only one XOR gate introduced to the load. The actions of inputs and outputs of flip-flops are not, and should not be, affected. The dynamic power is determined by the supply voltage, load capacitance and toggle rate (activity factor). The supply voltage is supposed to be constant, so the dynamic power can be analyzed from the other two factors. First, in clock gated flip-flop, the wasted clock toggles are gated, which resulted in a reduced toggle rate. The dynamic power will decrease with the clock toggle rate. Secondly, the XOR gate increases the load capacitance of the flip-flop. With the same toggle rate at the output Q, the dynamic power will increase with the load capacitance.

The dynamic power of flip-flop can be roughly modeled as a function of toggle rates of each port. Based on equation (3), the dynamic power of the flip-flop can be expressed as:

P_{eff}=α·(C_{L}+C_{SC})·V_{DD}²·f (5)

Flip-flops generally include four action states. The first state happens when the data input and clock signal are all toggling; the second state happens when clock toggles and the data input does not; the third state happens when data input toggles and the clock does not; and the last state happens when neither the data input nor the clock toggles. The effective toggle rate depends on both data input and the clock input. So a function is defined to describe the effective toggle rate:

α=ψᵢ(TR_{clk}ⁱ,TR_{d}ⁱ) (6)

Where, α is the effective toggle rate; TR_{clk}ⁱ is the toggle rate of clock signal in state i; TR_{d}ⁱ is the toggle rate of the data input in state i; i ranges in (I,II,III,IV) and denotes the state.

Looking into the function and structure of clock gating, it can be seen that the clock gating only has a major effect on state two, in which clock gating techniques try to eliminate the clock toggles. In this state, the toggle rate of data input is 0. So the effective toggle rate in this state is only depending on TR_{clk}^{II}.

P_{II}=ψ_{II}(TR_{clk}^{II},TR_{d}^{II})·Cₜₒₜ·V_{DD}²·f

P_{II}=ψ′(TR_{clk}^{II})Cₜₒₜ·V_{DD}²·f (7)

Because the action in state II is monotonous (clock toggling, data input holding), so the function ψ′(TR_{clk}^{II}) is linear. Suppose ψ′(TR_{clk}^{II})=k·T_{clk}^{II}, then:

P_{II}=TR_{clk}^{II}·k·Cₜₒₜ·V_{DD}²·f (8)

As a result, P_{saved} is obtained:

$${P}_{saved}^{i} = {P}_{H}^{i} = {TR}_{clk}^{i \_ II} \cdot {k}^{i} \cdot {C}_{tot}^{i} \cdot {( {V}_{DD}^{i} )}^{2} \cdot f \\ {P}_{saved} = {\sum }_{i = 1}^{N} {P}_{II}^{i} = {\sum }_{i = 1}^{N} {TR}_{clk}^{i \_ II} \cdot {P}_{unit}^{i} \qquad ( 9 )$$

where Pᵤₙᵢₜ is a parameter depending on the cell library, and it can be extracted from the library.

There is minor effect on the power of other states, which is caused by the introduced load capacitance of the XOR gate. This effect can be compensated in the calculation of Pₑₓₜᵣₐ, which is the extra power introduced by clock gating logics.

Assuming N flip-flops are to be gated together, in BSC style clock gating, the extra logics include: NXOR gates, (N−1) OR gates (approximately), 1 latch and 1 AND gate. Note, with different synthesis tools, the logic cells used for clock gating and the logic numbers might vary. For example, synthesis tools might use 3-input OR gate or 2-input OR gate. In the payoff function according to one embodiment of this invention, it is assumes that the OR gate are all 2-input cells. However, this assumption does not affect the accuracy of the payoff function; because in the payoff function, only estimating the trend of the power varying is needed, rather than the precise power consumption. Also, the power varying trend is sufficient for the clustering algorithm.

In bus-specific clock gating structure, each gated flip-flop needs an extra XOR gate to detect the states of input and output of flip-flop. Because of the delay, the toggle rate of XOR is twice of that of corresponding flip-flop output.

$${P}_{extra \_ XOR}^{i} = 2 * {TR}_{FF \_ Q}^{i} \cdot {P}_{unit \_ XOR}^{i} \\ {P}_{extra \_ XOR} = 2 * {\sum }_{i = 1}^{N} {TR}_{FF \_ Q}^{i} \cdot {P}_{unit \_ XOR}^{i} \qquad ( 10 )$$

The number of OR gates needed for clock gating depends on the synthesis tool, but one can generally use (N−1) 2-input OR gate to estimate the power varying trend. The toggle rate of each OR gate is affected by the combination of inputs. To leave a margin for the payoff function, the maximum of the two inputs can be used as the output toggle rate. Note, the OR gate consists a tiny part of the extra power. So a rough estimation will be enough; the extra power of OR gates:

$${P}_{extra \_ OR} = {\sum }_{i = 1}^{N - 1} Max ( {TR}_{FF \_ Q}^{i} , {TR}_{FF \_ Q}^{i + 1} ) \cdot {P}_{unit \_ XOR}^{i} \qquad ( 11 )$$

In a bus-specific clock gating structure, there will be only one latch. The latch has one similarity with flip-flop. It also has multiple operation states, however, unlike the flip-flop, of which just one state can be considered; the latch is an exotic device, whose all operation states should be considered. Since input of the latch is a constant clock signal, the enable signal has two states. So the latch has two operation states: 1) enable; and 2) disabled:

Pₑₓₜᵣₐ_{_{—}}_{latch}=Pₛₜₐₜₑ_{_{—}}_{I}+TRₜₒₜ*Pᵤₙᵢₜ_{_{—}}_{latch} (12)

where TRₜₒₜ is the total toggle rate after a group of flip-flops is gated together.

In the bus-specific clock gating structure, there is only one AND gate. However, it is the largest part of the extra power consumption. Because the AND gate has a very large fan out, N flip-flops. Its toggle rate is TRₜₒₜ. The power model is given as:

Pₑₓₜᵣₐ_{_{—}}_{AND}=TRₜₒₜ·Pᵤₙᵢₜ_{_{—}}_{AND}+N·TRₜₒₜ·P_{FF}_{_{—}}_{load} (13)

As discussed above, the extra power introduced by the XOR gate to the flip-flops is to be considered:

$${P}_{extra \_ com} = {\sum }_{i = 1}^{N} N \cdot {TR}_{FF \_ Q}^{i} \cdot {P}_{XOR \_ load} \qquad ( 14 )$$

Substituting equation (9)-(14) into equation (4), provides the final form of the payoff function:

$${F}_{payoff} = {\sum }_{i = 1}^{N} {TR}_{clk}^{i \_ II} \cdot {P}_{unit}^{i} - ( {\sum }_{i = 1}^{N} {TR}_{FF \_ Q}^{i} \cdot {P}_{unit \_ XOR}^{i} + {\sum }_{i = 1}^{N - 1} Max ( {TR}_{FF \_ Q}^{i} , {TR}_{FF \_ Q}^{i + 1} ) \cdot {P}_{unit \_ XOR}^{i} + {P}_{state \_ I} + {TR}_{tot} * {P}_{unit \_ latch} + {TR}_{tot} \cdot {P}_{unit \_ AND} + N \cdot {TR}_{tot} \cdot {P}_{FF \_ load} + {\sum }_{i = 1}^{N} N \cdot {TR}_{FF \_ Q}^{i} \cdot {P}_{XOR \_ load} ) \qquad ( 15 )$$

After obtaining the activity correlation matrix and payoff function, the flip-flops can be classified. The clustering algorithm in CBSC allows for listing the flip-flops in ascending order of their toggle rate, and with each flip-flop, searching the activity correlation matrix for the most correlated flip-flops and grouping them together as a cluster. Then the payoff function is used to obtain the power gain. If the power gain is larger than a threshold and is increasing, then the method continues to add the most correlated flip-flop of the rest to the group. The steps are repeated, looking for correlated flip-flops, until the payoff function stop increasing. FIG. 4 illustrates pseudo code for the clustering algorithm according to one embodiment of this invention.

The proposed payoff function, according to different embodiments of this invention, was tested on part of ISCAS'89 benchmark circuits (s298, s9234, and s38417) to verify the validity. The proposed CBSC was tested on all ISCAS'89 benchmark circuits, and compared with the OBSC technique described above, as well as an automatic clock gating (ACG) technique used in Synopsys Power Compiler.

The payoff function is one of the key parts of the CBSC. It is used to measure the performance of each classification scheme, and find out an optimal clustering scheme. So, the first step of the experiment was to verify the validity of the payoff function. The subject circuits had 14, 211, and 1636 flip-flops respectively. They represented the whole benchmark, because their numbers of flip-flops are standing in the small amount group (flip-flop number range from 3 to 29), moderate amount group (flip-flop number range from 32 to 211) and large amount group (flip-flop number ranging from 534 to 1728) in the whole set of benchmarks.

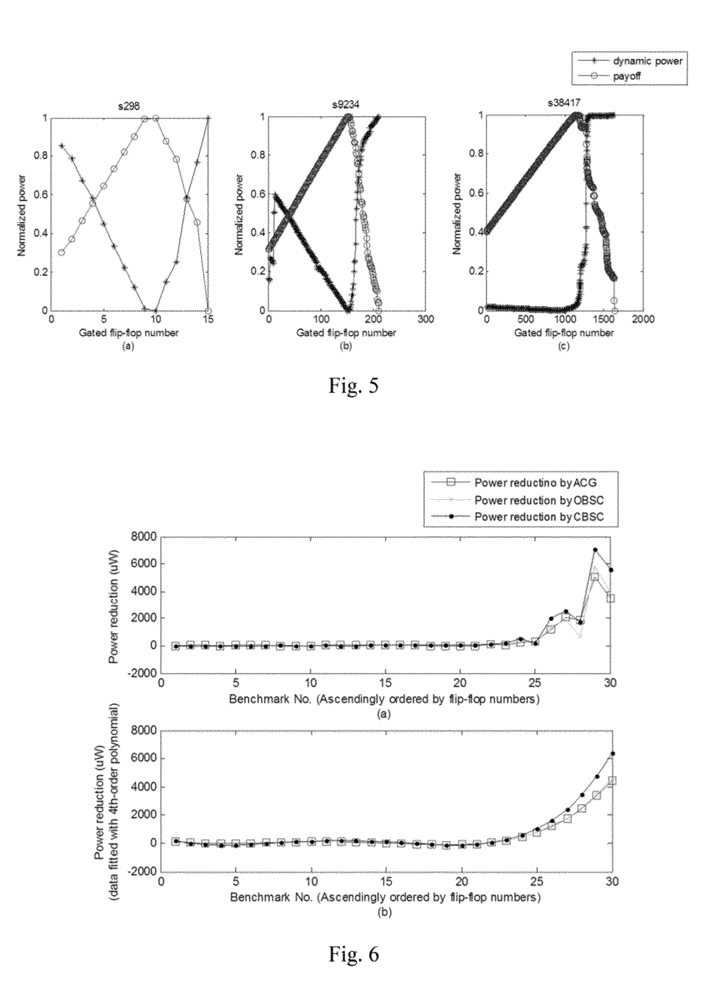

In the verification of the payoff function, the flip-flops were all sorted in ascending order, and then the flip-flop were added into the gated group one by one. In each step the power consumption was recorded. FIG. 5 shows the verification results, with the dynamic power curve showing the power measurement of each step. In the meanwhile, the payoff function was used to predict the power gain of each step. In FIG. 5, the payoff curve shows the power gain of each clock gating step. The results are all normalized to 1.

From FIG. 5, it is seen that the payoff function can predict the power changing trend. In all the (a), (b) and (c) part of FIG. 5, the lowest power consumption occurs where the highest power gain in the payoff function curve occurs. Also, the power measurement curve rises when the payoff function curve drops; and the power measurement curve drops when the payoff function curve rises. The payoff function provides the ability to measure the performance of different clock gating schemes.

With the payoff function, the CBSC algorithm was implemented to cluster all the flip-flops in each benchmark circuit for dynamic power optimization. Table 3 shows the clustering results of the CBSC algorithm, as well as the OBSC gating scheme. The OBSC gating scheme can be considered as a specific case of the CBSC, which has only one cluster. In the CBSC technique, variable clusters for each benchmark circuits are made based on the power reduction effect.

TABLE 3
Comparison of gated Flip-flops

| Gated FFs | |
|---|---|
| OBSC | CBSC |

| | FF | FF | Cluster | FF | Cluster |
|---|---|---|---|---|---|
| Benchmark | No. | No. | No. | No. | No. |
| S27 | 3 | 1 | 1 | 1 | 1 |
| S298 | 14 | 9 | 1 | 9 | 4 |
| S344 | 15 | 5 | 1 | 5 | 2 |
| S349 | 15 | 5 | 1 | 5 | 2 |
| S382 | 21 | 16 | 1 | 16 | 3 |
| S386 | 6 | 4 | 1 | 4 | 2 |
| S400 | 21 | 16 | 1 | 16 | 3 |
| S420 | 16 | 13 | 1 | 14 | 5 |
| S444 | 21 | 14 | 1 | 16 | 3 |
| S510 | 6 | 4 | 1 | 2 | 1 |
| S526 | 21 | 14 | 1 | 16 | 4 |
| S526n | 21 | 14 | 1 | 16 | 4 |
| S641 | 19 | 13 | 1 | 13 | 4 |
| S713 | 19 | 12 | 1 | 13 | 4 |
| S820 | 5 | 3 | 1 | 3 | 1 |
| S832 | 5 | 3 | 1 | 3 | 1 |
| S838 | 32 | 28 | 1 | 30 | 5 |
| S953 | 29 | 23 | 1 | 21 | 7 |
| S1196 | 18 | 5 | 1 | 6 | 3 |
| S1238 | 18 | 5 | 1 | 6 | 3 |
| S1423 | 74 | 38 | 1 | 49 | 11 |
| S1488 | 6 | 3 | 1 | 5 | 2 |
| S1494 | 6 | 3 | 1 | 5 | 2 |
| S5378 | 179 | 95 | 1 | 100 | 15 |
| S9234 | 211 | 150 | 1 | 168 | 12 |
| S13207 | 638 | 436 | 1 | 481 | 28 |
| S15850 | 534 | 288 | 1 | 424 | 51 |
| S35932 | 1728 | 951 | 1 | 1317 | 114 |
| S38417 | 1636 | 999 | 1 | 1295 | 50 |
| S38584 | 1426 | 148 | 1 | 636 | 107 |

The power analysis tool used in the experiment was Synopsys Power Compiler. For comparison, four groups of power consumption data were measured, three of which were implemented with different clock gating technique. In Table 4, the first column shows the benchmark circuit in ISCAS'89; the second column shows the flip-flop numbers of each circuit; the third column shows the dynamic power consumption of the original circuit without any power optimization scheme; the fourth column shows the power consumption of the benchmark circuits with automatic clock gating technique in Synopsys Power Compiler; the fifth column shows the power consumption of the benchmark circuits with OBSC gating scheme; and the last column shows the power consumption of benchmark circuits with the invented CBSC gating scheme.

TABLE 4
Power measurements

| | FF | Dynamic Power (uW) | | | |
|---|---|---|---|---|---|
| Circuit | No. | Original | ACG | OBSC | CBSC |
| S27 | 3 | 28.877 | 29.413 | 27.504 | 27.504 |
| S298 | 14 | 128.510 | 134.473 | 85.439 | 88.540 |
| S344 | 15 | 168.784 | 161.185 | 152.516 | 152.780 |
| S349 | 15 | 170.154 | 161.185 | 154.030 | 154.333 |
| S382 | 21 | 161.364 | 154.160 | 81.600 | 77.547 |
| S386 | 6 | 120.351 | 82.776 | 102.185 | 103.606 |
| S400 | 21 | 161.907 | 156.229 | 82.151 | 78.093 |
| S420 | 16 | 130.053 | 83.701 | 63.148 | 64.921 |
| S444 | 21 | 162.987 | 152.635 | 85.112 | 79.745 |
| S510 | 6 | 115.300 | 148.970 | 109.368 | 111.465 |
| S526 | 21 | 184.348 | 155.413 | 106.470 | 103.311 |
| S526n | 21 | 183.734 | 154.646 | 105.920 | 102.607 |
| S641 | 19 | 167.708 | 135.207 | 112.667 | 107.895 |
| S713 | 19 | 169.978 | 135.208 | 116.302 | 115.248 |
| S820 | 5 | 191.520 | 102.238 | 178.696 | 178.696 |
| S832 | 5 | 199.308 | 110.255 | 185.329 | 185.329 |
| S838 | 32 | 238.749 | 135.666 | 83.536 | 79.821 |
| S953 | 29 | 275.718 | 281.259 | 218.652 | 196.430 |
| S1196 | 18 | 383.054 | 350.295 | 368.210 | 364.992 |
| S1238 | 18 | 404.398 | 350.553 | 389.612 | 386.379 |
| S1423 | 74 | 663.965 | 629.267 | 478.240 | 442.739 |
| S1488 | 6 | 252.270 | 201.765 | 240.630 | 238.060 |
| S1494 | 6 | 254.934 | 212.080 | 242.486 | 240.650 |
| S5378 | 179 | 1816.6 | 1563.5 | 1305.3 | 1276.2 |
| S9234 | 211 | 1072.7 | 754.754 | 855.035 | 852.637 |
| S13207 | 638 | 4769.7 | 2696.1 | 2783.6 | 2234.3 |
| S15850 | 534 | 3920.8 | 2708.2 | 2516.2 | 1904.3 |
| S35932 | 1728 | 18137.7 | 14623.5 | 14196.6 | 12517.6 |
| S38417 | 1636 | 12473.0 | 7403.8 | 6692.2 | 5411.0 |
| S38584 | 1426 | 15280.2 | 13386.0 | 14636.3 | 13524.3 |

FIG. 6 includes data from Table 4, and compares the performances of the three clock gating techniques. In FIG. 6, the X-axis denotes the sorted (by flip-flop number) benchmark indices; the Y-axis denotes the absolute power reduction. The curve marked by rectangles denotes the power reduction by ACG technique; the curve marked by cross signs denotes the power reduction by the OBSC gating technique; and the curve marked by dots denotes the power reduction by proposed CBSC technique. FIG. 6(a) shows the direct curves, and FIG. 6(b) shows the curves resulted from 4-th order polynomial data fitting algorithm.

FIG. 6 shows that when the flip-flop number is small, the difference between the three techniques is tiny. However, when the flip-flop numbers increase, the CB SC technique saved much more power than the other two, and the advantage is increasing with the flip-flop number.

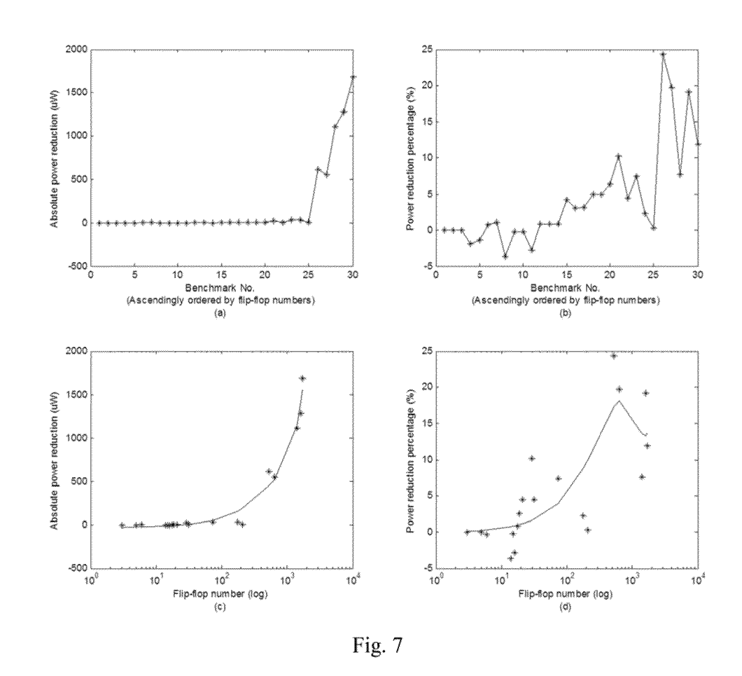

FIG. 7 summarizes a comparison between OBSC and CBSC using the Synopsys Power Compiler. FIG. 7(a) shows the power reduction of CBSC versus OBSC. The X-axis denotes the benchmark circuit index by ascending order of flip-flop numbers, the Y-axis denotes the power reduction of CBSC versus OBSC. FIG. 7(a) shows that as the flip-flop number increased, the CBSC saved more and more power than OBSC. In FIG. 7(b), the advantage of CBSC over OBSC is compared in percentage scale, and it shows that, in the small-number benchmark circuits, OBSC was a little better than CBSC. However, the advantage is limited by 5%. As the flip-flop number increases, the CBSC reduced as much as 24.31% power on the basis of the OBSC. This is a reasonable result, because in small-number flip-flop circuits, the CBSC may not have many clustering options, and a small number flip-flop usually means the circuit scale is also small, and the flip-flops are less correlated.

FIG. 7(c) shows the relation between the advantage of CBSC over OBSC and the flip-flop numbers. The X-axis denotes the flip-flop number in logarithmic scale; the Y-axis denotes the power reduction of CBSC on the basis of OBSC. The curve is obtained by 4-order polynomial data fitting algorithm. FIG. 7(c) shows that the power reduction of CBSC over OBSC was exponentially increasing with the number of flip-flop in logarithmic scale. In FIG. 7(d), the X-axis denotes the flip-flop number in logarithmic scale, and the Y-axis denotes the power reduction of CBSC on the basis of OBSC, in percentage scale. The curve is data fitted by 4-order polynomial data fitting algorithm. FIG. 7(d) shows that the curve was above zero and swung around 15%, and in conclusion, the CBSC was overall better than the OBSC.

Thus, the invention provides a new data structure, namely an activity correlation matrix, to denote the activity correlation of flip-flops in a circuit. The activity correlation matrix is based on the activity correlation. This feature makes it suitable for dynamic power optimization. The invention further provides a payoff function to measure the performances of clock gating scheme. The proposed payoff function is efficient in time and can measure the dynamic power performances. The activity correlation matrix and payoff function together provide for the clustering bus-specific clock gating method of this invention.

The invention illustratively disclosed herein suitably may be practiced in the absence of any element, part, step, component, or ingredient which is not specifically disclosed herein.

While in the foregoing detailed description this invention has been described in relation to certain preferred embodiments thereof, and many details have been set forth for purposes of illustration, it will be apparent to those skilled in the art that the invention is susceptible to additional embodiments and that certain of the details described herein can be varied considerably without departing from the basic principles of the invention.

What is claimed is:

1. A method for improving power consumption in integrated circuits, the method comprising grouping circuits by activity correlation and clock gating as a function of the grouped circuits.

2. The method of claim 1, wherein the circuits comprise flip-flop circuits.

3. The method of claim 2, further comprising reducing clock toggles as a function of the grouped circuits.

4. The method of claim 1, wherein the grouping comprises correlating the circuits as a function of circuit toggle.

5. The method of claim 4, further comprising grouping the circuits in an activity correlation matrix.

6. The method of claim 1, further comprising correlating activity of circuits during a predetermined number of clock cycles.

7. The method of claim 6, further comprising determining a correlation between a first circuit and a second circuit during the predetermined number of clock cycles as a function of an absolute value of a toggle count difference between the first circuit and the second circuit.

8. The method of claim 7, further comprising normalizing the absolute value with a plurality of absolute values determined between pairs of a plurality of circuits during the predetermined number of clock cycles.

9. The method of claim 1, further comprising:
grouping the circuits in an activity correlation matrix;
sorting the circuits from the activity correlation matrix in ascending order as a function of a toggle rate;
clustering the circuits having a highest correlation in a group;
continue adding the circuits having the next highest correlation to the group until a power gain is no longer increasing and/or is above a predetermined threshold; and
gating the circuits not within the group.

10. A method for improving power consumption in integrated circuits, the method comprising:
correlating flip-flop circuits as a function of circuit activity;
classifying the correlated circuits into a plurality of clusters; and
gating at least one of the clusters including lower activity flip-flop circuits.

11. The method of claim 10, further comprising determining a number of clusters to gate as a function of power savings, wherein the power savings is determined as a function of power reduction by the gating and power used for the correlating and classifying steps.

12. The method of claim 10, further comprising correlating flip-flop circuits for a predetermined input vector timeframe.

13. The method of claim 10, further comprising reducing clock toggles as a function of the clustered flip-flop circuits and/or the gating.

14. The method of claim 10, further comprising correlating the flip-flop circuits as a function of circuit toggle.

15. The method of claim 10, further comprising grouping the flip-flop circuits in an activity correlation matrix.

16. The method of claim 10, further comprising correlating activity of the flip-flop circuits during a predetermined number of clock cycles.

17. The method of claim 16, further comprising determining a correlation between a first flip-flop circuit and a second flip-flop circuit during the predetermined number of clock cycles as a function of an absolute value of a toggle count difference between the first flip-flop circuit and the second flip-flop circuit.

18. The method of claim 17, further comprising normalizing the absolute value with a plurality of absolute values determined between pairs of a plurality of flip-flop circuits during the predetermined number of clock cycles.

19. The method of claim 10, further comprising:
grouping the flip-flop circuits in an activity correlation matrix;
sorting the flip-flop circuits from the activity correlation matrix in ascending order as a function of a toggle rate;
clustering the flip-flop circuits having a highest correlation in a group;
continue adding the flip-flop circuits having the next highest correlation to the group until a power gain is no longer increasing and/or is above a predetermined threshold; and
gating the flip-flop circuits not within the group.
